(19) United States
(12) Patent Application Publication
(10) Pub. No.: US 2026/0293588 A1
(43) Pub. Date: Sep. 24, 2026

(54) DEPLOYMENT METHOD FOR CONSISTENT POSITIONING RESULTS ACROSS MULTIPLE APPARATUSES AND METHOD FOR IMPROVING POSITIONING PERFORMANCE THEREOF

(71) Applicant: CHROMA ATE INC., Taoyuan City (TW)

(72) Inventors: TING-WEI CHEN, Taoyuan City (TW); JUNG-CHIEH TSAO, Taoyuan City (TW); WEI-CHE CHANG, Taoyuan City (TW); SHIH-YAO PAN, Taoyuan City (TW)

(21) Appl. No.: 19/531,721

(22) Filed: Feb. 6, 2026

(30) Foreign Application Priority Data
Mar. 21, 2025 (TW) 114110737

(51) Int. Cl. H10P 72/00; H10P 72/50; H10P 74/20; H10W 46/00

(52) U.S. Cl. CPC H10P 72/0608; H10P 72/50; H10P 74/203; H10W 46/301

(57) ABSTRACT

A deployment method for consistent positioning results across multiple apparatuses and a method for improving positioning performance thereof applied to a testing apparatus including a movement device and an imaging device. The method includes a positioning step, a rotation correction step and a coordinate compensation information establishment step. The positioning performance of each of multiple testing apparatuses is improved by using the same standard sheet including multiple reference marks arranged in an array to obtain a corresponding coordinate compensation information table for each testing apparatus. Thus, when each testing apparatus is driven based on a same recipe, position compensation control can be performed according to the corresponding coordinate compensation information table, enabling these apparatuses to be connected in terms of coordinate position control, thereby achieving consistent positioning results across multiple apparatuses and improving efficiency.

### BACKGROUND OF THE INVENTION

### Field of the Invention

The present disclosure relates to a positioning technique for testing apparatuses in the field of water manufacturing, and more particularly to a deployment method for consistent positioning results for platforms across multiple apparatuses and a method for improving positioning performance thereof.

### Description of the Prior Art

It is necessary to perform corresponding tests in numerous manufacturing phases during a manufacturing process of semiconductor wafer to ensure the yield rate of wafer.

In a common testing apparatus, wafer is placed on a carrier unit by means of a transportation device or manually. The carrier unit is, for example, a combination of a chuck providing functions such as clamping, attracting or attaching and a carrier for carrying wafer, or may be only a chuck on which wafer is directly placed. The carrier unit is configured on a movement platform to form a wafer carrier. The wafer carrier may be driven to move within the testing apparatus, enabling the position of wafer carried thereon to be changed in the testing apparatus to facilitate proceeding of a testing procedure. The testing apparatus may be configured to drive the wafer carrier to perform a corresponding movement operation on a testing plane according to a testing instruction.

For example, in some testing procedures, for an imaging device that does not need to be moved in a testing apparatus, various testing positions on wafer may be sequentially arranged within a testing region of the imaging device by multiple movement operations of the wafer carrier, further allowing the imaging device to sequentially perform corresponding testing procedures at the individual testing positions on the wafer.

Thus, whether the wafer carrier can be precisely moved to the positions of target coordinates to achieve accurate positioning results becomes critical. Conventionally, for example, a laser interferometer is used to correct each of an X-axis and a Y-axis of a wafer carrier in a testing apparatus; however, this results in a rather lengthy correction time. Moreover, coordinate systems having undergone correction are independent, and are not correlated with other coordinate systems of other testing apparatuses on a production line. Accordingly, in order for each target coordinate position in a testing procedure to exhibit relatively stable and accurate positioning results, a greater amount of correction tasks as well as more time have to be involved.

### SUMMARY OF THE INVENTION

In some embodiments of the present disclosure, in addition to improving positioning accuracy, coordinate systems of a plurality of testing apparatuses may also become correlated to further enhance overall positioning accuracy.

In some embodiments of the present disclosure, a reproducibility issue of control results among various testing apparatuses at a mass production scale is solved, allowing the same recipe to be directly applied to all testing apparatuses on a mass production line, and reducing the necessity for individual fine-tuning of each of the testing apparatuses.

According to some embodiments, a method for improving positioning performance is provided and applied to a testing apparatus including a movement device and an imaging device. The testing apparatus is configured to drive a wafer carrier of a movement device, such that at least a portion of a standard sheet carried by the wafer carrier is able to enter a field of view of the imaging device. The standard sheet includes a plurality of reference marks arranged in an array. The method for improving positioning performance includes a positioning step, a rotation correction step and a coordinate compensation information establishment step. The positioning step is for aligning a reference position on the standard sheet with a baseline position of the field of view. The rotation correction step is for correcting, based on a geometric relation formed by at least two reference marks arranged in a same column or a same row, the standard sheet to a state without rotation deviation. The coordinate compensation information establishment step is for obtaining corresponding offset information of the wafer carrier in each of a plurality of target coordinates to establish a coordinate compensation information table, as a compensation basis when the wafer carrier is subsequently driven. The wafer carrier is driven to sequentially align the baseline position with these target coordinates as driving destinations. Once the wafer carrier has arrived at the driving destination of one of the target coordinates, a target position of the target coordinate in an image of the field of view is obtained based on distance information among these reference marks. Moreover, an offset amount between the target position and the baseline position in the field of view is used as corresponding offset information.

According to some embodiments, in the coordinate compensation information establishment step, at least one fine coordinate between two adjacent target coordinates may be included. Fine offset information corresponding to this fine coordinate is obtained by means of interpolation according to two sets of offset information corresponding to these two target coordinates, and may be incorporated into the coordinate compensation information table. Once the wafer carrier is driven to this fine coordinate, the corresponding fine offset information may be obtained from the coordinate compensation information table to achieve a highly accurate positioning result of the wafer carrier.

According to some embodiments, the reference position may be a center position of the standard sheet. The reference position may be a center of the field of view.

According to some embodiments, each reference mark may correspond to one target coordinate. Once driving the wafer carrier to arrive at one target coordinate is completed, the position of the reference mark closest to the baseline position may be defined as the target position above.

According to some embodiments, the rotation correction step may include a correction procedure. The correction procedure may refer to steps of: obtaining a connecting line formed by two reference marks, moving the standard sheet in a column direction or a row direction, and rotating the wafer carrier according to an included angle formed by the connecting line relative to the column direction or the row direction to eliminate the included angle. Furthermore, the rotation correction step may include two rounds of the correction procedure. In the first round of the correction procedure, the standard sheet is moved to a proximal range close to the baseline position. In the second round of the correction procedure, the standard sheet is moved to a distal range away from the baseline position.

According to some embodiments, a deployment method for consistent positioning results across multiple apparatuses is provided. With a configuration of a standard sheet including a plurality of reference marks arranged in an array, each of testing apparatuses each including a movement device and an imaging device performs the above method for improving positioning performance based on the same standard sheet. This is for obtaining a corresponding coordinate compensation information table for each of the testing apparatuses. When each of the testing apparatuses is driven based on the same recipe, position compensation control is performed according to the corresponding coordinate compensation information table, further allowing each of the testing apparatuses to achieve reproducibility of control results.

Accordingly, with the establishment of the coordinate compensation information table pertinent to each of the testing apparatuses, the positioning performance of each of the testing apparatuses can be improved. Moreover, the multiple testing apparatuses can be connected in terms of coordinate position control based on the same standard sheet, thereby achieving consistent positioning results across multiple apparatuses and improving efficiency.

### BRIEF DESCRIPTION OF THE DRAWINGS

FIG. 1 is a flowchart of a method for improving positioning performance according to some embodiments;

FIG. 2 is a functional block diagram of a testing apparatus according to some embodiments;

FIG. 3 is a schematic diagram of an image of a proximal range during a process of coordinate compensation information establishment according to some embodiments;

FIG. 4 is a schematic diagram of an image of a distal range during a process of coordinate compensation information establishment according to some embodiments; and

FIG. 5 is a schematic diagram of imaging during a process of rotation correction according to some embodiments.

### DETAILED DESCRIPTION OF THE EMBODIMENTS

The objectives, features, and advantages of the present disclosure are hereunder illustrated with specific embodiments, depicted with drawings, and described below.

In the disclosure, descriptive terms such as “a” or “one” are used to describe the unit, component, structure, device, module, portion, section or region, and are for illustration purposes and providing generic meaning to the scope of the present invention. Therefore, unless otherwise explicitly specified, such description should be understood as including one or at least one, and a singular number also includes a plural number.

In the disclosure, descriptive terms such as “include, comprise, have” or other similar terms are not for merely limiting the essential elements listed in the disclosure, but can include other elements that are not explicitly listed and are however usually inherent in the units, components, structures, devices, modules, portions, sections or regions.

In the disclosure, the terms similar to ordinals such as “first” or “second” described are for distinguishing or referring to associated identical or similar components, structures, portions, or regions, and do not necessarily imply the orders of these components, structures, portions, sections or regions in a spatial aspect. It should be understood that, in some situations or configurations, the ordinal terms could be interchangeably used without affecting the implementation of the present invention.

In the disclosure, the term “coupled” used refers to two or multiple elements or devices being directly and physically in contact with each other, or indirectly and physically in contact with each other, or may refer to two or more elements or devices operating or acting with each other or directly or indirectly electrically (by electricity or electrical signals) connected to each other.

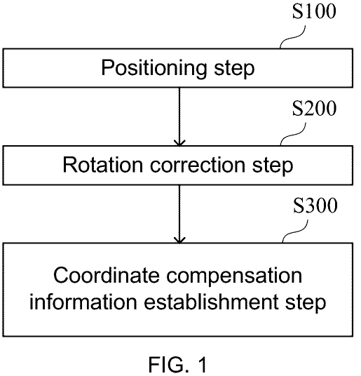

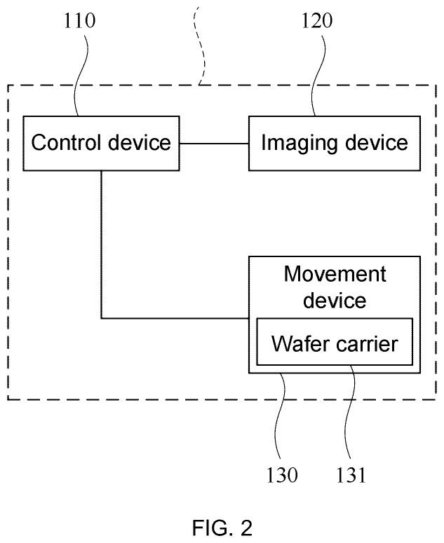

Refer to FIG. 1 and FIG. 2. FIG. 1 shows a flowchart of a method for improving positioning performance according to some embodiments. FIG. 2 shows a functional block diagram of a testing apparatus according to some embodiments.

The testing apparatus 100 includes, for example but not limited to, being configured with a control device 110, an imaging device 120 and a movement device 130. The imaging device 120 and the movement device 130 are individually coupled to the control device 110. The control device 110 is a control computer of the testing apparatus 100, and may be used to receive an instruction from a remote end and an operation from a local end. A wafer carrier 131 is one component of the movement device 130. The wafer carrier 131 is for carrying wafer to be tested. The movement device 130 allows the wafer carrier 131 to be moved in the testing apparatus 100 by a track or other components with mobility.

For example, the wafer carrier 131 is mounted on an XYθ movement platform, and the testing apparatus 100 may drive the wafer carrier 131 of the movement device 130 to allow wafer to be tested or other objects carried thereon to move and/or rotate on a testing plane according to a control instruction of the control device 110. This testing plane is constructed by an X-axis and a Y-axis perpendicular to each other of the XYθ movement platform.

The imaging device 120 of the testing apparatus 100 is usually configured to provide an imaging function of image capturing for at least a portion of a region referred to as a “field of view”) on the testing plane from an angle of view in a top-down or sideways manner. However, the present disclosure is not limited to such example, and other angles of view are also suitable in this embodiment. An image thus obtained may undergo operation analysis to obtain related information (for example, information such as position and distance) of the image. The operation analysis task may be performed by the control device 110 and/or the imaging device 120 itself. The imaging device 120 includes, for example but not limited to, a combination of a camera module and a lighting module.

The alignment ability of the testing apparatus 100 may be associated with the positioning ability during movement, the optical imaging ability during imaging and the calculation ability during operation analysis. For the positioning ability during movement, these embodiments disclosed by the present application are used to improve the positioning performance of the testing apparatus, providing enhanced positioning repeatability and accuracy.

For an automated testing application environment configured with multiple testing apparatuses 100 on a production line, a batch of wafer to be tested has respectively corresponding testing procedures (or referred to as “formulae”), and individual dies on the wafer to be tested need to be sequentially and precisely moved to specific testing positions in the field of view of the imaging device 120 for proceeding of an optical testing procedure. If the movement device 130 fails to precisely move the wafer carrier 131 to the specific testing position in the field of view, imaging of corresponding dies may be incomplete (for example, only an image of a half or even less of a die is captured) in a way the corresponding testing procedure cannot be completed.

In these embodiments disclosed by the present application, by establishing a coordinate compensation information table associated with the movement device 130 pertinent to each testing apparatus 100, offset information of each target coordinate can be learned to allow the control device 110 to use the offset information as a compensation basis. Thus, in subsequent control (for example, testing of a mass amount of wafer to be tested), the wafer carrier 131 can be precisely moved to the corresponding position, further allowing corresponding dies on the wafer to be tested carried thereon to be accurately located at the specific testing positions in the field of view of the imaging device 120.

The number of target coordinates associated with the coordinate compensation information table may be determined according to the corresponding wafer to be tested and a required testing range, and does not necessarily mean that corresponding offset information have to be obtained for all movable positions of the wafer carrier 131 in the testing apparatus 100. Thus, during implementation, adaptive adjustment may be made according to attributes of the wafer to be tested and the corresponding testing range and purpose.

Furthermore, the establishment of the coordinate compensation information table is founded on a standard sheet. The standard sheet is, for example, a sheet similar to wafer to be tested but not required to be manufactured with various circuit layers. The standard sheet may be formed to include scribe lines or other marks thereon by means of a semiconductor manufacturing technique, and these inscribe lines or marks are regarded as reference marks. Owing to higher precision of semiconductor manufacturing techniques (for example, processes such as lithography and etching), position relations, distance relations, and horizontal and vertical relations in terms of arrangement of these reference marks arranged on the standard sheet are provided with high accuracy. Thus, in the field of view of the imaging device 120, a geometric relation formed by one or a combination of the position relations, distance relations, and horizontal and vertical relations among these reference marks is used as a basis for position correction. An approach based on the above also ensures the level of accuracy of the coordinate compensation information table pertinent to each of the testing apparatuses 100. The form of the reference marks may be asterisk-shaped, X-shaped, L-shaped or in other shapes, which are suitable in the various embodiments disclosed by the present application.

Furthermore, when the coordinate compensation information table is established for all of multiple testing apparatuses 100 on the basis of the same standard sheet, these testing apparatuses 100 are able to mutually connect to one another in terms of coordinate position control on the basis of this standard sheet. In other words, when one recipe (for example, including path control associated with coordinate positions) is executed on these testing apparatuses 100, positioning results associated with coordinate positions in the testing procedure can render higher reproducibility on these testing apparatuses 100. Thus, consistent positioning results across multiple apparatuses can be achieved.

When a coordinate position is accurately reproduced in the various testing apparatuses 100, in this recipe, other optical testing steps performed by the imaging device 120 can be accurately performed in these testing apparatuses 100 without having to conduct additional correction or adjustment. Moreover, the same applies in future modification of the recipe, hence further enhancing production efficiency.

The method for improving positioning performance is to establish the coordinate compensation information table exclusive for each testing apparatus 100. As shown in FIG. 1, the method for improving positioning performance includes a positioning step S100, a rotation correction step S200 and a coordinate compensation information establishment step S300. The positioning step S100 and the rotation correction step S200 may be performed in exchanged orders, provided that they are completed before step S300.

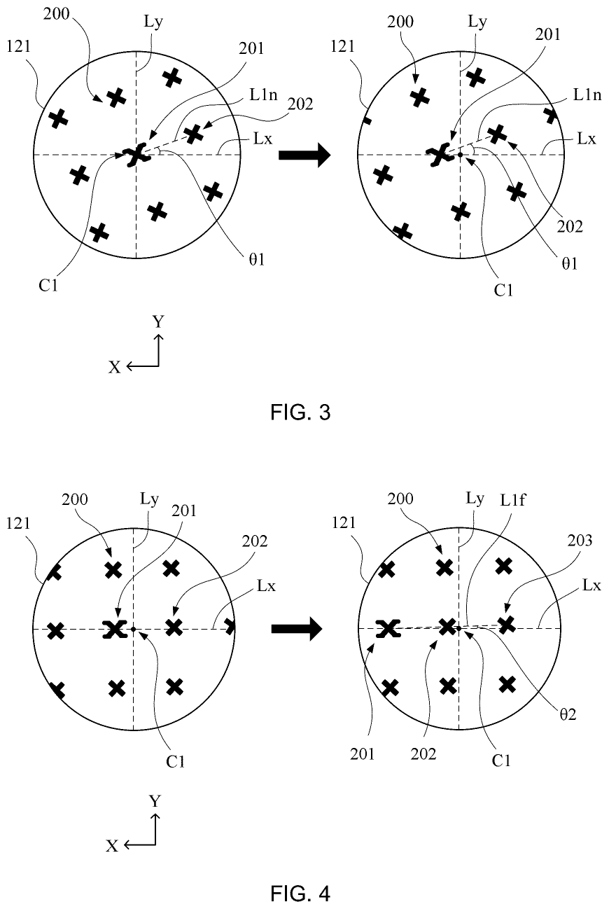

Refer to FIG. 1, FIG. 3 and FIG. 4. FIG. 3 shows a schematic diagram of an image of a proximal range during a process of coordinate compensation information establishment according to some embodiments. FIG. 4 shows a schematic diagram of an image of a distal range during a process of coordinate compensation information establishment according to some embodiments.

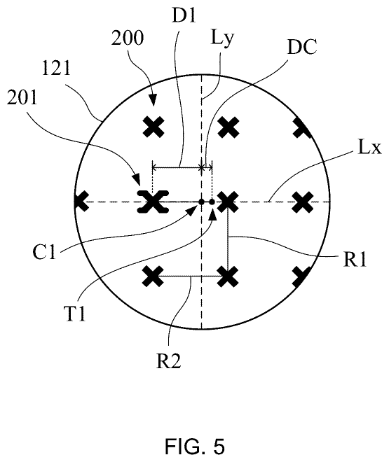

In the positioning step S100, the wafer carrier 131 carrying a standard sheet is driven and moved to a required position by controlling the movement device 130. The so-called “moved to a required position” means that a reference position 201 of the standard sheet can align with a baseline position C1 in a field of view 121 of the imaging device 120. In FIG. 3 and FIG. 4, a center line of the field of view 121 is labeled as a vision field center line L2. The outline of the field of view 121 in FIG. 3, FIG. 4 and FIG. 5 below appears as a circle for example; however, the present application is not limited to such example, and other shapes are also suitable in various embodiments of the present application.

The reference position may be designated as one of multiple reference marks 200 on the standard sheet, for example, a reference mark 201 additionally assigned with a numeral. It should be understood that the reference mark 201 is still considered the reference mark 200. In some embodiments, the reference position may be a center position of the standard sheet. Moreover, in some embodiments, the baseline position C1 may be a center of the field of view 121. However, the above is dependent on an operation decision of a user, and is not limited to necessarily being a center position. Hence, in the description below, in addition to 200 as the numeral of the reference marks, some of the reference marks with special purposes may be additionally assigned with one numeral, for example, 201, 202 and 203. However, these reference marks with special purposes are still within the scope of the reference mark 200. For better illustration purposes, these reference marks with special purposes are merely represented by special numerals, for example, 201, 202 and 203.

The purpose of the rotation correction step S200 is to have an XY movement direction of the wafer carrier 131 of the movement device 130 to match an arrangement direction of these reference marks 200 on the standard sheet. These reference marks 200 are arranged in an array to form an arrangement including a plurality of columns and a plurality of rows.

For better illustration purposes, FIG. 3 and FIG. 4 merely depict some of the reference marks 200 arranged in a array configuration. In the embodiments in FIG. 3 and FIG. 4, the center of the reference mark 201 on the standard sheet serves as a reference position, and is marked by a special character. The positioning step S100 above may determine, by whether the center of the reference mark 201 in the field of view 121 coincides with the baseline position C1, whether positioning is completed.

The level of accuracy may be adjusted as needed. For example, the coincidence of position may contain a slight tolerable error, such that a condition may be defined as whether the center of the reference mark 201 substantially coincides with the baseline position C1 as a determination basis for whether the positioning task is completed. This is also applicable to related determination in various embodiments.

In the rotation correction step S200, based on the movement of the wafer carrier 131 in the X direction or the Y direction, the rotation function of the movement device 130 may be driven according to a state of the geometric relation correspondingly established by two reference marks, such that the standard sheet is free from any rotational deviation. That is to say, the purpose is to have the X movement direction of the wafer carrier 131 be parallel to the row direction of these reference marks 200 on the standard sheet, and the Y movement direction of the wafer carrier 131 be parallel to the column direction of these reference marks 200 on the standard sheet.

FIG. 3 depicts a correction procedure for a proximal range. In this embodiment, two reference marks (denoted as the reference marks 201 and 202 in FIG. 3) arranged in the same row form a geometric relation of a connecting line L1n. From the left of FIG. 3, it appears that an included angle θ1 between the trajectory of the connecting line L1n and a vision field horizontal line Lx can be directly observed; however, this is merely an example, and in fact the included angle θ1 is extremely small. Thus, the standard sheet is moved in the proximal range (the standard sheet is moved to the left in the example shown in FIG. 3), so that the included angle θ1 between the trajectory of the connecting line L1n and the vision field horizontal line Lx can be emphasized. The wafer carrier 131 is then rotated, and with further comparison by the imaging device 120 with the image in the field of view 121, the included angle θ1 can be eliminated. Once the included angle θ1 is eliminated, the X and Y movement directions of the wafer carrier 131 can match the arrangement direction of these reference marks 200 on the standard sheet to a certain extent.

In some other embodiments, two rounds of correction procedure may be performed in the rotation correction step S200. In addition to the first round of correction procedure (the correction procedure for a proximal range) shown in FIG. 3, a second round of correction procedure (a correction procedure for a distal range) shown in FIG. 4 may be further implemented.

FIG. 4 depicts a correction procedure for a distal range, and shows a state subsequent to the first round of correction procedure in FIG. 3. The standard sheet is further moved to the left and moved farther away, for example, moved to be close to or adjacent to an edge of the standard sheet (for better illustration purposes, the example in FIG. 4 does not show that the standard sheet is moved to close to or adjacent to the edge of the standard sheet). In this embodiment, two reference marks (denoted as the reference marks 201 and 203 in FIG. 4) arranged in the same row form a geometric relation of a connecting line L1f. From the right of FIG. 4, it observed that a slight included angle θ2 is still present between the trajectory of the connecting line L1f and the vision field horizontal line Lx. Thus, the standard sheet is further moved in the distal range, so that the included angle θ2 between the trajectory of the connecting line L1f and the vision field horizontal line Lx can be emphasized. The wafer carrier 131 is again rotated, and with further comparison by the imaging device 120 with the image in the field of view 121, the included angle θ2 can then be eliminated. Once the included angle θ2 is eliminated, it is further ensured that the X and Y movement directions of the wafer carrier 131 can match the arrangement direction of these reference marks 200 on the standard sheet.

The alignment of the tracks for moving the wafer carrier 131 on the X direction and the Y direction may be completed by correction before the testing apparatus 100 is shipped out of the factory. For example, with the coordination of the imaging device 120, the vision field horizontal line Lx and the vision field vertical line Ly in the field of view 121 can be correspondingly parallel to the movement trajectories of the tracks of the wafer carrier 131 in the X direction and the Y direction.

The coordinate compensation information establishment step S300 is for obtaining corresponding offset information of the wafer carrier 131 in each of a plurality of target coordinates to establish a coordinate compensation information table in the control device 110. When the wafer carrier 131 is subsequently driven, the control device 110 is able to perform position compensation according to the coordinate compensation information table established beforehand.

In the coordinate compensation information establishment step S300, based on an arranged scanning path (including multiple target coordinates), various target coordinates on the scanning path can be sequentially aligned with the baseline position C1 in the field of view 121 as a target to perform driving. Upon arriving at each target coordinate, the field of view 121 is imaged by the imaging device 120 to further obtain the situation shown in FIG. 5, for example. In FIG. 5, if a movement device can be precisely driven in terms of driving to this target coordinate, the target coordinate can be understood as being precisely aligned with the baseline position C1 in the field of view 121.

For each target coordinate, the distance to the reference position of the standard sheet can be calculated. After step S100 and step S200 are completed and before the wafer carrier 131 is further driven, the reference position of the standard sheet is the baseline position C1. First of all, it is assumed that, on the standard sheet, the corresponding position of the target coordinate on the standard sheet is a target position T1. In FIG. 5, if the movement device 130 can precisely align the baseline position C1 in the field of view 121 with the target position T1, it means that the movement device 130 is able to precisely move the wafer carrier 131 in terms of control of this target coordinate, and the offset information at this point in time is 0. Conversely, it means that the movement device 130 contains an offset in terms of control of this target coordinate, and a corresponding offset amount have to be obtained as the offset information.

By regarding this target coordinate as a driving destination, with the image obtained in the field of view 121 and on the basis of the actual distance information (including, for example but not limited to, column spacing information R1 and row spacing information R2) among these reference marks 200 present on the standard sheet, the corresponding position of the target coordinate (that is, the target position T1) on the standard sheet can be calculated. That is to say, after the movement device 130 drives the wafer carrier 131 by regarding the target coordinate as the driving destination, the baseline position C1 is expected to coincide with the target position T1. Accordingly, when the target position T1 on the standard sheet is not moved to the baseline position C1, it means that the movement device 130 contains an offset in terms of driving to this target coordinate.

As shown in FIG. 5, by regarding this target coordinate as the driving destination, the target position T1 is not moved to the baseline position C1. The movement device 130 merely moves leftward the reference position (the center) of the reference mark 201 on the standard sheet by a distance D1, and is located at an offset distance DC from the target position T1. The control device 110 of the testing apparatus 100 may then perform additional control to coincide the target position T1 with the baseline position C1 according to the image captured by the imaging device 120 in the field of view 121 and the control on the movement device 130. The purpose of the above is to eliminate the offset distance DC, such that when the target coordinate is regarded as the driving destination, the movement device 130 is able to precisely drive the wafer carrier 131 and align the baseline position C1 with the target position T1. That is to say, the additional control further includes coordinate movement information additionally used by the movement device 130 in the offset information.

Thus, after the corresponding offset information of each required target coordinate is obtained, that is, once a coordinate compensation information table for this testing apparatus 100 is completed, subsequent control performed on the movement device 130 of this testing apparatus 100 allows the wafer carrier 131 to be precisely driven to the target coordinate. FIG. 5 depicts an example with merely one direction (the X direction) containing an offset, and situations where both directions (the X direction and the Y direction) contain offsets are also suitable in the various embodiments above.

In the embodiments above, calculation of distances in an image is based on the distance information among these reference marks 200 on the standard sheet. In some other embodiments, each required target coordinate may be further made on the standard sheet. Thus, although determination is made according to the architecture of the distance information present among the reference marks 200, a standard sheet including more reference marks is used in a further embodiment. In other words, in this further embodiment, each target position T1 has a corresponding reference mark on the standard sheet. The offset distance DC appears between the reference position (for example, the center of the reference mark) of the reference mark corresponding to the target position T1 and the baseline position C1. Once the wafer carrier 131 is moved to the target coordinate as the destination and driving of the movement device 130 is completed, the position of one reference mark 200 closest to the baseline position C1 usually serves as the target position T1 above.

In some other embodiments, other coordinates (or referred to as fine coordinates) between target coordinates may also be incorporated into the coordinate compensation information table. In a feasible approach, for example, fine offset information corresponding to one fine coordinate corresponding to two target coordinates (both having corresponding offset information) may be estimated by interpolation, for example, estimating offset information of one fine coordinate in the middle of two target coordinates, or estimating offset information of one fine coordinate next to two target coordinates. In terms of a geometric relation, a fine coordinate and two target coordinates corresponding thereto may form a connecting line.

Thus, in the implementation of the embodiment above, a corresponding coordinate compensation information table for each testing apparatus can be obtained. In an environment where a mass amount of testing have to be performed on a substantial amount of objects to be tested and corresponding testing procedures have to be driven and performed based on one recipe on each of these testing apparatuses, position compensation control can be performed by the corresponding testing apparatus on a target position according to a coordinate compensation information table established beforehand, hence achieving accurate positioning ability during movement as well as providing enhanced positioning reproducibility and accuracy.

As used herein, the terms “about,” “approximately,” “substantially,” or “essentially” typically mean “any approximation of a given value” or “any approximation of a given range.” The degree of approximation may vary depending on the relevant field and should be consistent with the broadest reasonable interpretation understood by one of ordinary skill in the art to encompass similar embodiments and all modifications based on such variations. In some embodiments, these terms typically mean within twenty percent of the “given value” or “given range,” further within ten percent, and still further within five percent. Numerical values provided herein are approximate, indicating that unless expressly stated otherwise, such numerical values may be inferred to fall within the scope of “about,” “approximately,” “substantially,” or “essentially,” or are meant to include other approximations thereof.

The present invention has been disclosed through various embodiments. However, it should be understood by those skilled in the art that the embodiments are merely illustrative and not restrictive of the scope of the present invention. After perusing this specification, persons skilled in the art may come up with other aspects and embodiments without departing from the scope of the present disclosure. All equivalent variations and replacements of the aspects and the embodiments must fall within the scope of the present disclosure. Therefore, the scope of the protection of rights of the present invention shall be defined by the appended claims.

What is claimed is:

1. A method for improving positioning performance, applied to a testing apparatus comprising a movement device and an imaging device, the testing apparatus configured to drive a wafer carrier of the movement device such that at least a portion of a standard sheet carried thereon is able to enter a field of view of the imaging device, the standard sheet comprising a plurality of reference marks arranged in an array; the method for improving positioning performance comprising:
a positioning step of aligning a reference position on the standard sheet with a baseline position of the field of view;
a rotation correction step of rendering, based on a geometric relation formed by at least two of the reference marks arranged in a same column or a same row, the standard sheet to a state without rotational deviation; and
a coordinate compensation information establishment step for obtaining corresponding offset information of the wafer carrier in each of a plurality of target coordinates to establish a coordinate compensation information table, as a compensation basis when the wafer carrier is subsequently driven,
wherein, when the wafer carrier is driven to sequentially align the baseline position with the target coordinates as driving destinations and has arrived at the driving destination of one of the target coordinates, a target position of the target coordinate in an image of the field of view is obtained based on distance information among the reference marks, and an offset amount between the target position and the baseline position in the field of view is used as the corresponding offset information.

2. The method for improving positioning performance according to claim 1, wherein the coordinate compensation information establishment step further comprises at least one fine coordinate between two adjacent of the target coordinates, and fine offset information corresponding to the fine coordinate is obtained by interpolation according to two sets of the offset information corresponding to two of the target coordinates and incorporated into the coordinate compensation information table.

3. The method for improving positioning performance according to claim 1, wherein the reference position is a center position of the standard sheet, and the baseline position is a center of the field of view.

4. The method for improving positioning performance according to claim 1, wherein each of the reference marks corresponds to one of the target coordinates, and once driving the wafer carrier to arrive at one of the target coordinates is completed, a position of the reference mark closest to the baseline position is the target position.

5. The method for improving positioning performance according to claim 1, wherein the rotation correction step comprises:
a correction procedure of obtaining a connecting line formed by the two reference marks, moving the standard sheet in a column direction or a row direction, and rotating the wafer carrier according to an included angle formed by the connecting line relative to the column direction or the row direction to eliminate the included angle.

6. The method for improving positioning performance according to claim 5, wherein the rotation correction step comprises two rounds of the correction procedure, wherein the standard sheet is moved to a proximal range close to the baseline position in a first round of the correction procedure, and the standard sheet is moved to a distal range away from the baseline position in a second round of the correction procedure.

7. A deployment method for consistent positioning results across multiple apparatuses, comprising:
performing a method for improving positioning performance by a plurality of testing apparatuses each comprising a movement device and an imaging device based on a standard sheet configured to include a plurality of reference marks arranged in an array, to obtain a coordinate compensation information table corresponding to each of the testing apparatuses, wherein each of the testing apparatuses performs position compensation control according to the corresponding coordinate compensation information table when driven based on a recipe,
wherein, each of the testing apparatuses is configured to drive a wafer carrier of the movement device such that at least a portion of the standard sheet carried by the wafer carrier is able to enter a field of view of the imaging device, and the method for improving positioning performance performed by each of the testing apparatuses comprises:
a positioning step of aligning a reference position on the standard sheet with a baseline position of the field of view;
a rotation correction step of rendering, based on a geometric relation formed by at least two of the reference marks arranged in a same column or a same row, the standard sheet to a state without rotational deviation; and
a coordinate compensation information establishment step of obtaining corresponding offset information of the wafer carrier in each of a plurality of target coordinates to establish the coordinate compensation information table corresponding to the testing apparatus, wherein, when the wafer carrier is driven to sequentially align the baseline position with the target coordinates as driving destinations and has arrived at the driving destination of one of the target coordinates, a target position of the target coordinate in an image of the field of view is obtained based on distance information among the reference marks, and an offset amount between the target position and the baseline position in the field of view is used as the corresponding offset information.

8. The deployment method according to claim 7, wherein the coordinate compensation information establishment step further comprises at least one fine coordinate between two adjacent of the target coordinates, and fine offset information corresponding to the fine coordinate is obtained by interpolation according to two sets of the offset information corresponding to two of the target coordinates and incorporated into the coordinate compensation information table.

9. The deployment method according to claim 7, wherein the reference position is a center position of the standard sheet, and the baseline position is a center of the field of view.

10. The deployment method according to claim 7, wherein each of the reference marks corresponds to one of the target coordinates, and once driving the wafer carrier to arrive at one of the target coordinates is completed, a position of the reference mark closest to the baseline position is the target position.

11. The deployment method according to claim 7, wherein the rotation correction step comprises:
a correction procedure of obtaining a connecting line formed by the two reference marks, moving the standard sheet in a column direction or a row direction, and rotating the wafer carrier according to an included angle formed by the connecting line relative to the column direction or the row direction to eliminate the included angle.

12. The deployment method according to claim 11, wherein the rotation correction step comprises two rounds of the correction procedure, wherein the standard sheet is moved to a proximal range close to the baseline position in a first round of the correction procedure, and the standard sheet is moved to a distal range away from the baseline position in a second round of the correction procedure.
